(19) United States
(12) Patent Application Publication
(10) Pub. No.: US 2022/0376132 A1
(43) Pub. Date: Nov. 24, 2022

(54) METHOD FOR MANUFACTURING SEMICONDUCTOR ELEMENT

(71) Applicant: KYOCERA CORPORATION, Kyoto-shi, Kyoto (JP)

(72) Inventors: Takehiro NISHIMURA, Kusatsu-shi (JP); Yutaka KUBA, Soraku-gun (JP); Katsuaki MASAKI, Kyoto-shi (JP); Kentaro MURAKAWA, Uji-shi (JP); Toshihiro KOBAYASHI, Kyotanabe-shi (JP)

(73) Assignee: KYOCERA CORPORATION, Kyoto-shi, Kyoto (JP)

(21) Appl. No.: 17/764,430

(22) PCT Filed: Sep. 30, 2020
(86) PCT No.: PCT/JP2020/037240

§ 371 Date: Mar. 28, 2022

(30) Foreign Application Priority Data
Sep. 30, 2019 (JP) 2019-179582

(51) Int. Cl. H01L 33/00; C30B 25/04; H01L 21/02; H01L 21/304

(52) U.S. Cl. CPC H01L 33/007; C30B 25/04; H01L 21/02043; H01L 21/304

(57) ABSTRACT

A method for manufacturing a semiconductor element of the present disclosure includes: a step of preparing a substrate; a first element forming step of forming a first semiconductor layer in a first region on a surface of the substrate; a first element separating step of separating the first semiconductor layer from the substrate; and a second element forming step of forming a second semiconductor layer in a second region on the surface of the substrate from which the first semiconductor layer is separated. Additionally, in the method for manufacturing a semiconductor element of the present disclosure, at least a portion of the second region overlaps the first region.

### TECHNICAL FIELD

The present disclosure relates to a method for manufacturing a semiconductor element.

### BACKGROUND ART

One example of the prior art is described in Patent Document 1 and Patent Document 2.

### CITATION LIST

### Patent Literature

Patent Document 1: JP 4638958 B

Patent Document 2: JP 2013-251304 A

### SUMMARY OF INVENTION

A method for manufacturing a semiconductor element of the present disclosure includes: a step of preparing a substrate; a first element forming step of forming a first semiconductor layer in a first region on a surface of the substrate; a first element separating step of separating the first semiconductor layer from the substrate; and a second element forming step of forming a second semiconductor layer in a second region on the surface of the substrate from which the first semiconductor layer is separated. Additionally, in the method for manufacturing a semiconductor element of the present disclosure, at least a portion of the second region is configured to overlap the first region.

### BRIEF DESCRIPTION OF DRAWINGS

FIG. 1A is a diagram for illustrating first and second manufacturing processes in a method for manufacturing a semiconductor element according to an embodiment of the present disclosure.

FIG. 1B is a diagram for illustrating a third manufacturing process in the method for manufacturing a semiconductor element according to an embodiment of the present disclosure.

FIG. 2 is an enlarged photograph showing a state where dislocation defects are generated on a substrate after an element separating step.

FIG. 3 is a diagram for illustrating a second mask forming step.

FIG. 4 is a diagram for illustrating a third mask forming step.

### DESCRIPTION OF EMBODIMENTS

Conventionally, a method for forming on a substrate a mask that includes openings and subsequently growing, by using a transversal epitaxial growth method, a semiconductor layer that forms a semiconductor element from an exposed surface exposed to the openings has been known as a method for manufacturing a semiconductor element (for example, see Patent Documents 1, 2). The grown semiconductor layer is transferred to a support substrate or the like and is separated from the substrate.

Additionally, Patent Document 2 describes that a peeling step of peeling a GaN-based semiconductor layer is performed and a mask forming step and a growing step are performed by using the peeled GaN substrate after the peeling step.

In such a method for manufacturing a semiconductor element, an improvement in productivity has been required.

Embodiments of the present disclosure will be described below with reference to the drawings. Note that the present invention relates to a method for manufacturing a semiconductor element. The semiconductor element manufactured by the manufacturing method according to the present invention may be, for example, a light emitting element, a light receiving element, or a Schottky barrier diode. Note that in the case of the light emitting element, the semiconductor element may be, for example, a light emitting diode (LED) and a laser diode (LD).

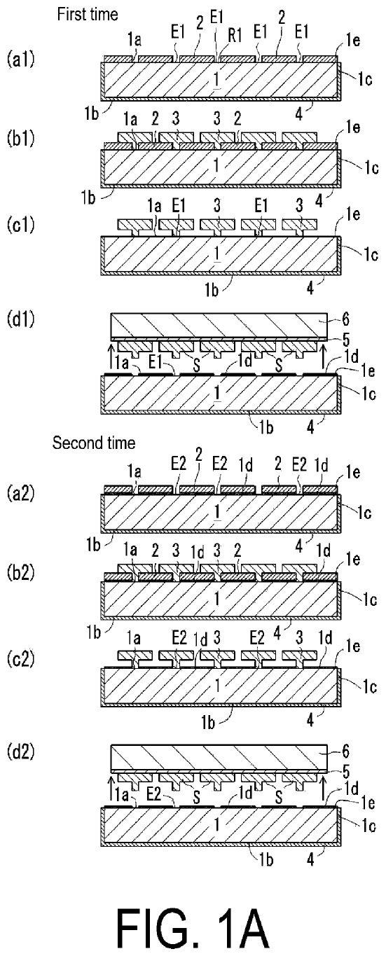

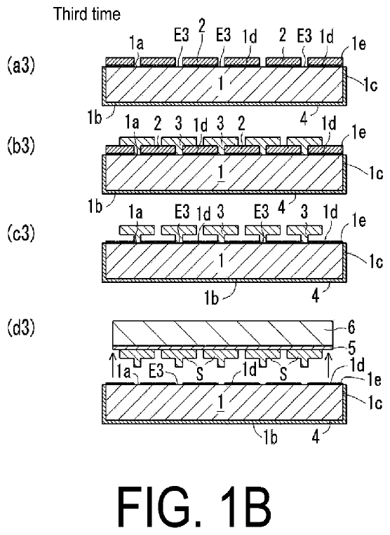

Steps a1, b1, c1, d1 in FIG. 1A correspond to a first manufacturing process of a semiconductor element where a substrate in an initial state, which is not used in manufacturing a semiconductor element, is used. Further, steps a2, b2, c2, d2 in FIG. 1A illustrate a substrate reuse step, and a substrate used at least once in manufacturing a semiconductor element is used. Furthermore, steps a3, b3, c3, d3 in FIG. 1B illustrate further a substrate reuse step. Steps a2 to d3 correspond to second and subsequent manufacturing processes of semiconductor elements.

In FIG. 1A, “step a1” indicates a first mask forming step, and “step a2” indicates a second mask forming step. “Step b1” indicates a first element forming step, and “step b2” indicates a second element forming step. “Step c1” indicates a first mask removing step, and “step c2” indicates a second mask removing step. “Step d1” indicates a first element separating step, and “step d2” indicates a second element separating step.

A substrate 1 commonly used in each of the steps is prepared before the step a1. The substrate 1 includes one main surface (hereinafter, also referred to as a first surface) 1a from which the growth of semiconductor crystals starts, and the other main surface (hereinafter, also referred to as a second surface) 1b located on the opposite side of the first surface 1a. A surface layer including the first surface 1a of the substrate 1 is formed of a nitride semiconductor. The substrate 1 used in the embodiment is, for example, a gallium nitride (GaN) substrate cut out from a GaN single crystal ingot.

The substrate 1 may be an n-type substrate obtained by doping impurities of Si or the like into a nitride semiconductor or a p-type substrate obtained by doping impurities of Mg or the like into a nitride semiconductor. The impurity concentration in the substrate 1 is, for example, about 1×10¹⁹ cm⁻³ or less. Also, in addition to a GaN substrate, a Si substrate, a sapphire substrate, a SiC substrate, or the like may be used as the substrate 1. The substrate 1 may be formed of the same type of material as a semiconductor layer 3 grown on the substrate 1, or may be formed of a different type of material therefrom. When the substrate 1 is formed of the same type of material as the semiconductor layer 3, for example, a GaN layer may be grown on the GaN substrate. Also, when the substrate 1 is formed of a different type of material from the semiconductor layer 3, a GaN layer may be grown on the Si substrate, the sapphire substrate, or the SiC substrate.

The substrate 1 is not limited to a substrate including the surface layer that is a GaN layer, and may be a substrate including the surface layer that is formed of a GaN-based semiconductor. Here, “GaN-based semiconductor” refers to a semiconductor formed of, for example, AlₓGa_{y}In_{z}N (0≤x≤1; 0≤y≤1; 0≤z≤1; x+y+z=1).

A protective layer 4 for suppressing deterioration of the substrate 1 or decomposition of the nitride semiconductor, which is caused by the steps described below, may be formed on the second surface 1b of the substrate 1, which is located on the opposite side of the first surface 1a, except for the first surface 1a from which the growth of semiconductor crystals starts. The protective layer 4 may include, for example, aluminum oxide, alumina, or the like. The protective layer 4 may also be formed on an end surface 1c of the substrate 1, which connects the first surface 1a and the second surface 1b.

In the present embodiment, the protective layer 4 is positioned on the second surface 1b of the substrate 1. As a result, deterioration of the second surface 1b of the substrate 1 can be reduced. In addition, growth conditions of semiconductor crystals can be stabilized, and mass productivity can be improved.

A method for manufacturing a semiconductor element where the substrate 1 in an initial state is used mainly corresponds to the steps a1, b1, c1, d1 in FIG. 1A. The method includes: the first mask forming step a1 of forming a first mask 21 on the first surface 1a of the substrate 1; the first element forming step b1 of forming the semiconductor layer 3 on the first surface 1a of the masked substrate 1; the first mask removing step c1 of removing a deposition inhibiting mask 2 (referred to as the first mask 21) by etching; and the first element separating step d1 of separating the semiconductor layer 3 from the first surface 1a of the substrate 1.

### (a1) First Mask Forming Step

In the first mask forming step a1, the deposition inhibiting mask 2 (first mask 21) that inhibits growth of semiconductor crystals (the semiconductor layer 3) is formed by using a photolithography technique and an etching technique in a predetermined pattern on the first surface 1a of the substrate 1 (GaN substrate). At this time, the first mask 21 is formed such that a first region R1 that is a portion of the first surface 1a of the substrate 1 is exposed. As a result, the semiconductor layer 3 can be formed in the first region R1 in the subsequent step.

Specifically, in the first mask forming step a1, first, the first mask 21 is formed on the entire surface of the first surface 1a. The first mask 21 is, for example, a silicon oxide (SiO₂) layer. In the first mask forming step a1, silicon oxide is laminated to approximately 30 to 500 nm on the first surface 1a by using a plasma chemical vapor deposition (PCVD) method or the like.

Next, a photoresist is applied to one surface (the front surface of the first mask 21), which is located on the opposite side of the other surface facing the first surface 1a, of the first mask 21 formed on the entire surface of the first surface 1a, and thus a resist layer (not illustrated) is formed. The photoresist may be a positive type photoresist or a negative type photoresist.

Next, a photomask (not illustrated) is prepared in which a mask pattern corresponding to the predetermined pattern of the first mask 21 is drawn. Subsequently, after positioning the photomask in a predetermined place relative to the substrate 1, the mask pattern drawn in the photomask is exposed and developed in the resist layer. The photomask may be, for example, a mask obtained by drawing a pattern with chromium (Cr), titanium (Ti), tungsten (W), or the like on a glass substrate.

Next, after curing the exposed and developed resist layer, unnecessary portions of the first mask 21, which are not covered by the resist layer are removed by HF (hydrofluoric acid)-based wet etching or dry etching with fluorine-based gas such as CF4. Subsequently, by removing the resist layer, the first mask 21 having the predetermined pattern can be formed on the first surface 1a of the substrate 1. The resist layer can be removed by using a known method such as lift-off with solvent or ashing.

An exposed surface E1 exposed from the region (upward opening) from which the first mask 21 is removed by etching is the first region R1 from which the first surface 1a is exposed. The first region R1 is a region from which the growth of semiconductor crystals starts in the first element forming step b1. Note that the first region R1 is formed, for example, in a plurality of strip shapes.

The opening width or groove width, which is a width (width of one of a plurality of strips) in a parallel direction (the left-right direction in FIG. 1A) of the exposed surface E1 may be, for example, 2 to 20 μm. In addition, in the embodiment, the width of the first mask 21 in the parallel direction is set to, for example, 150 to 200 μm.

The relationship between the width in the parallel direction of the first mask 21 and the width in the parallel direction of the exposed surface E1 may be set in consideration of a ratio between a crystal growth rate in a direction perpendicular to the first surface 1a of the substrate 1 and a crystal growth rate in a direction parallel to the first surface 1a of the substrate 1, of the semiconductor layer 3 formed in the first element forming step b1 subsequently performed, and in consideration of a thickness of the semiconductor layer 3 to be grown.

Further, the mask pattern of the first mask 21 may be a strip shape or a stripe shape, or may be a grid in which a plurality of strip-shaped bodies are arranged orthogonal to length and width directions. Any pattern may be used as long as the pattern is a so-called repeat design (pattern) in which openings partitioned at a constant spacing (repeat pitch) are repeated multiple times.

Furthermore, an edge region 1e near the end surface 1c in the first surface 1a may also be covered by the first mask 21. As a result, the semiconductor layer 3 is easily separated in the subsequent first element separating step d1, and the semiconductor layer 3 near the edge portion located at the end of the substrate 1 can be cleanly peeled off.

In addition, a material including silicon oxide such as SiO₂ is used as a mask material that forms the first mask 21 (deposition inhibiting mask 2). The deposition inhibiting mask 2 may be formed of a material in which the semiconductor layer does not grow from the surface of the mask material due to vapor phase growth. In addition to the material including silicon oxide, for example, an oxide such as zirconium oxide (ZrOₓ), titanium oxide (TiOₓ), aluminum oxide (AlOx) can be used. Note that the deposition inhibiting mask 2 may use a transition metal selected from chromium (Cr), tungsten (W), molybdenum (Mo), tantalum (Ta), niobium (Nb), and the like. Moreover, a method such as vapor deposition, sputtering, or coating and curing, which is suitable for the mask material can be appropriately used as a method for depositing the mask material.

### (b1) First Element Forming Step

In the first element forming step b1, semiconductor crystals are grown by epitaxial lateral growth (ELO) to expand from the exposed surface E1 that is the first region R1 to and over the first mask 21 adjacent thereto, and the semiconductor layer 3 (also referred to as a first semiconductor layer 31) forming a portion of the element is formed. In the present embodiment, the semiconductor layer 3 is a nitride semiconductor, and the nitride semiconductor is grown, by epitaxial growth, from the first surface 1a beyond upper edge openings of the grooves of the first mask 21 to the upper surface of the first mask 21.

A vapor phase growth method such as: a hydride vapor phase epitaxy (HVPE) method using a chloride as a Group III (Group 13 element) raw material; a metal organic chemical vapor deposition (MOCVD) method using an organic metal as a Group III raw material; or a molecular beam epitaxy (MBE) method can be used in the first element forming step b1.

For example, when a GaN layer that is the semiconductor layer 3 is grown by the MOCVD method, the substrate 1 on which the first mask 21 is formed by patterning is firstly inserted into a reaction chamber of an epitaxial device, and the substrate 1 is heated to a predetermined growth temperature, for example, 1050 to 1100° C. with the chamber supplied with hydrogen gas, nitrogen gas, or a mixed gas of hydrogen and nitrogen and a Group V raw material (containing a Group 15 element) gas such as ammonia.

Then, after the temperature of the substrate 1 is stable, a Group III (containing a Group 13 element) raw material such as trimethylgallium (TMG) is supplied in addition to the aforementioned mixed gas and Group V raw material to induce the epitaxial growth of the semiconductor layer 3 from the exposed surface E1 that is a crystal growth region (the first region R1).

At this time, by supplying a raw material gas of an n-type impurity such as Si or a p-type impurity such as Mg and adjusting the amount of doping, a desired conductivity type GaN layer can be obtained. In addition, before the grown crystal goes beyond the opening edge of the groove between the first masks 21 or the growth crystal fills the groove, the supply of the raw material may be stopped once to stop the growth of semiconductor crystals. In this way, before the supply of the raw material is started again, a “frangible portion” that allows the semiconductor layer 3 to easily separate in the first element separating step d1 may be formed as a partial layer or film.

As an example of the frangible portion, for example, in a case where the GaN layer is crystal grown, a layer made of mixed crystals of GaN, BN, InN, or the like may be formed as the frangible portion between an upper portion of the semiconductor layer 3 located on the opening side and a lower portion of the semiconductor layer 3 located on the exposed surface E1 side within the groove of the first region R1.

Alternatively, the semiconductor layer 3 made of AlₓGa_{y}In_{z}N (0≤x≤1; 0≤y<1; 0≤z≤1; x+y+z=1) having a lattice constant different from that of the crystal growth layer may be formed as a frangible portion. Further, a frangible portion having a superlattice structure may be formed by alternately layering AlGaN layers and GaN layers. The frangible portion may be a layer obtained by periodically changing growth conditions of crystals and alternately layering layers of large crystal grains and small crystal grains of GaN. The frangible portion may be a layer obtained by changing an impurity concentration, for example, by changing the concentration of silicon (Si) used as the n-type impurity of GaN.

When a semiconductor element S is separated from the substrate 1 by forming the frangible portion, stress is concentrated on the frangible portion, and cracks are easily generated. Thus, the semiconductor element S can be easily separated from the substrate 1.

In a case where the frangible portion is formed, the vapor phase growth of GaN is continued from the upper surface (front surface) of the frangible portion as the starting point. In a case where the frangible portion is not formed, the vapor phase growth of GaN is continued from the exposed surface E1 located, as the starting point, at an interval from the first region R1.

After the crystal growth surface exceeds the upper edge of the first mask 21, the semiconductor layer 3 grows in the horizontal direction (the left-right direction in FIG. 1A) along the upper surface of the deposition inhibiting mask 2. Therefore, threading dislocations or the like of the semiconductor layer 3 can be reduced.

Then, the first element forming step b1 ends before each semiconductor layer 3, the growth of which has started from the exposed surface E1 of the first region R1 comes into contact or overlaps with the first semiconductor layer 31 adjacent to the exposed surface E1. As a result, crystal defects such as cracks or threading dislocations that can occur when the adjacent semiconductor layers 3 are brought into contact with each other can be reduced.

Note that in the first element forming step b1, at least a portion of the semiconductor element may be formed, and in the first mask removing step c1, all configurations of the semiconductor element may not be formed. Additionally, when all configurations of the semiconductor element are not formed, the remaining configuration of the semiconductor element may be formed after the first mask removing step c1 or after the first element separating step d1. Also, the configuration of the semiconductor element may be appropriately formed depending on the semiconductor element type.

### (c1) First Mask Removing Step

After the first element forming step b1 is completed, the substrate 1 is removed from the vapor phase growth device (epitaxial device), and the first mask 21 is removed by using etchant by which the grown semiconductor layer 3 is not substantially affected.

For example, in the case of a mask formed of SiO₂ film, HF-based wet etching is performed to remove the first mask 21. The first mask 21 is removed by etching. As illustrated in (c1) of FIG. 1A, the first semiconductor layer 31 is formed into a substantially T-shape connected to the substrate 1 by a thin connection portion located on the exposed surface E1. Accordingly, separation of the first semiconductor layer 31 can be smoothly performed.

### (d1) First Element Separating Step

The first element separating step d1 is a step in which at least a portion of the semiconductor elements (for example, the first semiconductor layer 31) formed in the first element forming step b1 is separated from the substrate 1 by using a member such as a support substrate 6 including, on one surface (lower surface), an adhesive layer 5 made of solder in which a material such as AuSn is used or by using a jig, and thereby the individual semiconductor elements S are obtained.

For example, the support substrate 6 including the adhesive layer 5 on the lower surface is disposed facing the surface (first surface 1a) of the substrate 1 on which the first semiconductor layer 31 is formed. Subsequently, the support substrate 6 is pressed toward the substrate 1, and the adhesive layer 5 is heated, and thus the semiconductor 3 is adhered to the adhesive layer 5.

Thereafter, an external force is applied to the first semiconductor layer 31 adhered to the adhesive layer 5 and integrated thereto such that the first semiconductor layer 31 is peeled upward, and thus the first semiconductor layer 31 is pulled up from the first surface 1a of the substrate 1. As a result, the main bodies of the semiconductor elements S can be separated without scratching. The first element separating step d1 may include a step of dividing the first semiconductor layer 31 in accordance with the size of the semiconductor element S and a step of forming an electrode, a wire conductor, or the like on the first semiconductor layer 31. Note that in the event of dividing the first semiconductor layer 31, the first semiconductor layer 31 may be divided by cleaving the first semiconductor layer 31 along the cleavage surface.

Next, a substrate reuse step to be performed one or more times after the first element separating step d1 is completed will be described.

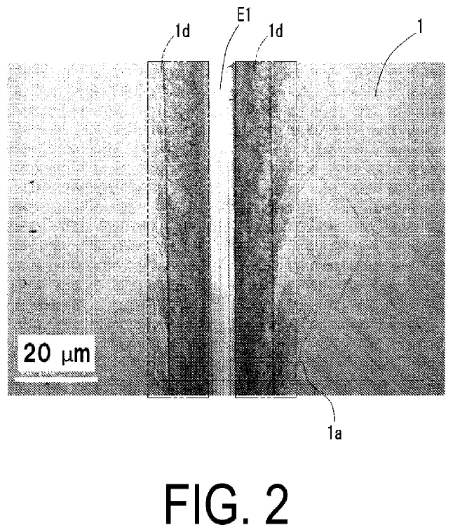

In the substrate 1 after the first semiconductor layer 31 is separated, pits from the first surface 1a to the inside of the substrate 1 and dislocation defects along the first surface 1a may occur in a region covered by the first mask 21 on the first surface 1a. FIG. 2 schematically illustrates a region (hereinafter, also referred to as a defect region) 1d where pits and dislocation defects are generated. FIG. 2 illustrates a state where dislocation defects are generated on the first surface 1a of the substrate 1.

It is difficult to grow high-quality semiconductor crystals from the defect region 1d. Therefore, in order to randomly re-form the deposition inhibiting mask 2 on the first surface 1a and re-grow semiconductor crystals from the first surface 1a, processing such as polishing needs to be applied to the first surface 1a.

In contrast, there is fewer pits in the first region R1 on the first surface 1a, that is, a region on the first surface 1a, which is connected to the semiconductor layer 3 (first semiconductor layer 31). Also, for example, as illustrated in FIG. 2, there is no dislocation defect in the first region R1, or dislocation defects exist in the first region R1 only with the surface density (for example, 1×10⁷/cm² or less) nearly equal to that of the substrate 1 in the initial state. Accordingly, the method for manufacturing a semiconductor element according to an embodiment of the present invention includes the substrate reuse step in which semiconductor crystals (a second semiconductor layer 32) are re-grown from a second region R2, at least a portion of which overlaps the first region R1. As a result, removals of pits and dislocation defects by polishing or the like can be reduced, and semiconductor crystals can be grown from the region having a pit density and a dislocation defect density that are nearly equal to those of the substrate 1 in the initial state, and thus, the productivity of semiconductor elements can be improved. Note that in the present embodiment, the second region R2 and the first region R1 are regions substantially coinciding with each other.

As illustrated in FIG. 1A, the substrate reuse step includes a second substrate reuse step including “step a2” to “step d2”. “Step a2” indicates the second mask forming step a2, “step b2” indicates the second element forming step b2, “step c2” indicates the second mask removing step c2, and “step d2” indicates the second element separating step d2. Note that in a state where polishing is not performed, the second substrate reuse step is performed on the first surface 1a exposed after the first element separating step d1 described above. Note that in the second substrate reuse step, a cleaning step of cleaning attachments adhered to the first surface 1a may be performed on at least a portion of the first surface 1a after the first element separating step d1 and before the second element forming step b2.

### (a2) Second Mask Forming Step

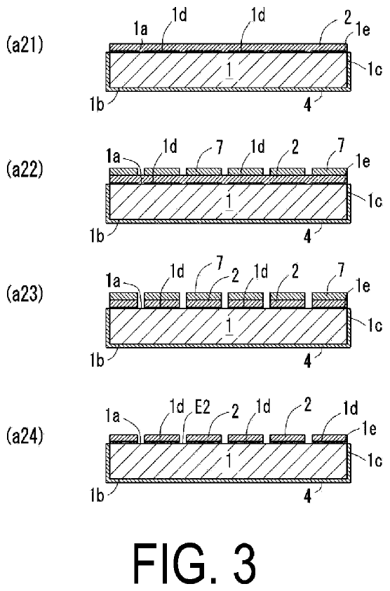

In the second mask forming step a2, by using the photolithography technique and the etching technique, a new deposition inhibiting mask 2 (also referred to as a second mask 22) is formed in the region including the forming position of the first mask 21 formed in the first mask forming step a1, and an exposed surface E2 (also referred to as a second crystal growth region (the second region R2)) not covered by the second mask 22 is exposed. The second mask forming step a2 includes first to fourth steps. In FIG. 3, “step a21” indicates the first step, “step a22” indicates the second step, “step a23” indicates the third step, and “step a24” indicates the fourth step.

(a21) First Step

In the first step a21, the deposition inhibiting mask 2 (second mask 22) is formed on the entire surface of the first surface 1a of the substrate 1. The second mask 22 may be, for example, a silicon oxide (SiO₂) layer having a thickness of approximately 30 to 500 nm. In the first step a21, for example, by using the PCVD method or the like, silicon oxide is laminated to approximately 30 to 500 nm on the first surface 1a.

(a22) Second Step

In the second step a22, first, a photoresist is applied to one surface (the front surface of the second mask 22), which is located on the opposite side of the other surface facing the substrate 1, of the second mask 22 formed in the first step a21, and thus a resist layer 7 is formed. The photoresist may be a positive type photoresist or a negative type photoresist.

Next, a photomask (not illustrated) is prepared in which a mask pattern corresponding to the mask pattern of the photomask used in the first mask forming step a1 is drawn. The photomask is, for example, a mask obtained by drawing a mask pattern with chromium (Cr), titanium (Ti), tungsten (W), or the like on a glass substrate. Subsequently, after positioning the prepared photomask in a predetermined place relative to the substrate 1 in the same manner as in the first mask forming step a1, the pattern drawn in the photomask is exposed and developed in the resist layer.

The photomask may be positioned relative to the substrate 1 based on the outer shapes of the substrate 1 and the photomask, the mask pattern drawn in the photomask, the position of the defect region 1d, or the like. Alignment marks for alignment are formed on the substrate 1 and the photomask, and in the first mask forming step a1 and the second mask forming step a2, the photomask may be positioned relative to the substrate 1 based on the alignment marks.

(a23) Third Step

In the third step a23, after curing the exposed and developed resist layer 7 into the predetermined pattern, unnecessary portions of the second mask 22, which are not covered by the resist layer 7 are removed by HF (hydrofluoric acid)-based wet etching or dry etching with fluorine-based gas such as CF4.

(a24) Fourth Step

In the fourth step a24, the resist layer 7 is removed by using a known method such as lift-off with solvent or ashing, and the exposed surface E2, at least a portion of which overlaps the exposed surface E1, is exposed.

With the second mask forming step a2 described above, the second region R2, at least a portion of which overlaps the first region R1, can be exposed on the first surface 1a of the substrate 1. The second region R2 may be included in the first region R1, and need not completely coincide with the first region R1. Also, the second region R2 may include the defect region 1d as far as normal semiconductor crystals can grow. Note that the second region R2 may be smaller than the first region R1.

In the second mask forming step a2, the second mask 22 may also be formed in the edge region 1e of the first surface 1a. As a result, the semiconductor layer 3 is easily separated in the second element separating step d2, and the semiconductor layer 3 present near the edge portion located at the end of the substrate 1 can be cleanly peeled off.

### (b2) Second Element Forming Step

In the second element forming step b2, semiconductor crystals are grown to expand from the exposed surface E2 that is the second region R2 to and over the upper surface of the second mask 22 adjacent thereto, and the semiconductor layer 3 (also referred to the second semiconductor layer 32) forming a portion of the element is formed. The second element forming step b2 may be in the same manner as the first element forming step b1.

### (c2) Second Mask Removing Step

After the second element forming step b2 is completed, the second mask 22 is removed by using etchant by which the grown second semiconductor layer 32 is not substantially affected. The second mask removing step c2 may be in the same manner as the first mask removing step c1.

### (d2) Second Element Separating Step

The second element separating step d2 is a step of separating the second semiconductor layer 32 from the substrate 1 and obtaining the individual semiconductor elements S. The second element separating step d2 may be in the same manner as the first element separating step d1.

In this manner, according to the method for manufacturing a semiconductor element according to an embodiment of the present invention, the first surface 1a of the substrate 1 is reused without removing pits and dislocation defects by polishing or the like after the first manufacturing process of a semiconductor element, and thus a second semiconductor element can be formed. As a result, the number of steps in manufacturing semiconductor elements is reduced, and thus the productivity can be improved.

In the substrate reuse step, the second substrate reuse step may be repeated two or more times. In the method for manufacturing a semiconductor element according to the embodiment, a large decrease of the thickness of the substrate 1 due to polishing or the like can be suppressed.

As illustrated in FIG. 1B, the substrate reuse step may further include a third substrate reuse step including “step a3” to “step d3”. “Step a3” indicates a third mask forming step a3, “step b3” indicates a third element forming step b3, “step c3” indicates a third mask removing step c3, and “step d3” indicates a third element separating step d3.

### (a3) Third Mask Forming Step

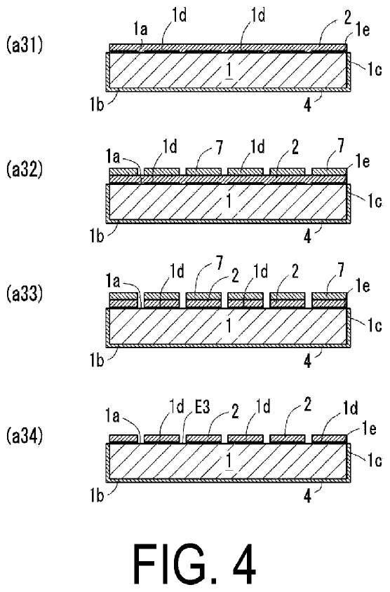

In the third mask forming step a3, by using the photolithography technique and the etching technique, a new deposition inhibiting mask 2 (a third mask 23) is formed in the region including the forming position of the second mask 22 formed in the second mask forming step a2, and an exposed surface E3 (also referred to as a third crystal growth region (a third region R3)) not covered by the third mask 23 is exposed. The third mask forming step a3 includes first to fourth steps. In FIG. 4, “step a31” indicates the first step, “step a32” indicates the second step, “step a33” indicates the third step, and “step a34” indicates the fourth step.

Note that after polishing is performed, the third mask forming step a3 may be performed on the first surface 1a exposed after the second element separating step d2 described above, or may be performed in a state where polishing is not performed. Even in a case where polishing is performed before the third mask forming step a3, the second mask removing step is interposed; therefore, wear of the substrate 1 can be reduced compared with a case where the substrate 1 is polished for each element separating step. Also, the third mask forming step a3 may be performed after the plurality of second substrate reuse steps. Note that each of the second substrate reuse step and the third substrate reuse step may be performed multiple times, and the number of second substrate reuse steps may be larger than the number of third substrate reuse steps.

(a31) First Step

In the first step a31, the deposition inhibiting mask 2 (also referred to as the third mask 23) is formed on the entire surface of the first surface 1a of the substrate 1. The third mask 23 may be, for example, a silicon oxide (SiO₂) layer having a thickness of approximately 30 to 500 nm. In the first step a31, for example, by using the PCVD method or the like, silicon oxide is laminated to approximately 30 to 500 nm on the first surface 1a.

(a32) Second Step

In the second step a32, first, a photoresist is applied to one surface (the front surface of the third mask 23), which is located on the opposite side of the other surface facing the substrate 1, of the third mask 23 formed in the first step a31, and thus the resist layer 7 is formed. The photoresist may be a positive type photoresist or a negative type photoresist.

Next, a photomask (not illustrated) is prepared in which a mask pattern corresponding to the mask pattern of the photomask used in the second mask forming step a2 is drawn. The photomask is, for example, a mask obtained by drawing a mask pattern with chromium (Cr), titanium (Ti), tungsten (W), or the like on a glass substrate. Subsequently, after positioning the prepared photomask in a predetermined place relative to the substrate 1 in the same manner as in the second mask forming step a2, the pattern drawn in the photomask is exposed and developed in the resist layer.

The photomask may be positioned relative to the substrate 1 based on the outer shapes of the substrate 1 and the photomask, the mask pattern drawn in the photomask, the position of the defect region 1d, or the like. Alignment marks for alignment are formed on the substrate 1 and the photomask, and in the second mask forming step a2 and the third mask forming step a3, the photomask may be positioned relative to the substrate 1 based on the alignment marks.

(a33) Third Step

In the third step a33, after curing the exposed and developed resist layer 7 into the predetermined pattern, unnecessary portions of the third mask 23, which are not covered by the resist layer 7 are removed by HF (hydrofluoric acid)-based wet etching or dry etching with fluorine-based gas such as CF4.

(a34) Fourth Step

In the fourth step a34, the resist layer 7 is removed by using a known method such as lift-off with solvent or ashing, and an exposed surface E3, at least a portion of which overlaps the exposed surface E2 is exposed.

With the third mask forming step a3 described above, the third region R3, at least a portion of which overlaps the second region R2, can be exposed on the first surface 1a of the substrate 1. The third region R3 may be included in the second region R2, and need not completely coincide with the second region R2. Also, the third region R3 may include the defect region 1d as far as normal semiconductor crystals can grow. Note that at least a portion of the third region R3 may overlap the first region R1. Further, the third region R3 may be separated from the first region R1. Furthermore, the third region R3 may be smaller than the first region R1.

In the third mask forming step a3, the third mask 23 may also be formed in the edge region 1e of the first surface 1a. As a result, the semiconductor layer 3 is easily separated in the third element separating step d3, and the semiconductor layer 3 present near the edge portion located at the end of the substrate 1 can be cleanly peeled off.

### (b3) Third Element Forming Step

In the third element forming step b3, semiconductor crystals are grown to expand from the exposed surface E3 that is the third region R3 to and over the upper surface of the third mask 23 adjacent thereto, and the semiconductor layer 3 (also referred to a third semiconductor layer 33) forming a portion of the element is formed. The third element forming step b3 may be in the same manner as the second element forming step b2.

### (c3) Third Mask Removing Step

After the third element forming step b3 is completed, the third mask 23 is removed by using etchant by which the grown third semiconductor layer 33 is not substantially affected. The third mask removing step c3 may be in the same manner as the second mask removing step c2.

### (d3) Third Element Separating Step

The third element separating step d3 is a step of separating the third semiconductor layer 33 from the substrate 1 and obtaining the individual semiconductor elements S. The third element separating step d3 may be in the same manner as the second element separating step d2.

In this manner, according to the method for manufacturing a semiconductor element according to the embodiment, the first surface 1a of the substrate 1 can be reused without removing pits and dislocation defects by polishing or the like after the first manufacturing process of a semiconductor element. As a result, the number of steps in manufacturing semiconductor elements is reduced, and thus the productivity can be improved.

As described above, according to the method for manufacturing a semiconductor element according to the embodiment, the productivity of semiconductor elements can be improved. Note that, after the second substrate reuse step (second element separating step d2) or the third substrate reuse step (third element separating step d3), a substrate growing step of increasing the thickness of the substrate 1 after the second element or the third element is peeled may be further provided. As a result, the substrate 1 itself can be regenerated, and a semiconductor element can be manufactured again. Note that the regeneration of the substrate 1 itself may be performed, for example, in the same way as a single crystal ingot. Specifically, for example, the substrate may be regenerated by vapor phase growth or liquid phase growth.

The present disclosure can be applied in many forms without departing from its spirit or key characteristics. Accordingly, the foregoing embodiment is merely illustrative in all respects, and the scope of the present disclosure is as set forth in the claims and is in no way limited by the specification. Furthermore, any variations or modifications that fall within the scope of the claims are also within the scope of the present disclosure.

For example, an example where the second substrate reuse step is performed without polishing the first surface 1a after the first element separating step d1 is described above; however, the first surface 1a may be polished after the first element separating step d1 and before the second element forming step b2. As a result, defects of the second element can be reduced, and thus the productivity of semiconductor elements can be improved.

Further, in the first element separating step d1, the first element may be separated along with a portion of the surface layer of the substrate 1 with which the first element is in contact. In this case, at the time of separating the first element, a portion of the surface layer of the substrate 1 can be removed, and the surface of the substrate 1 having few defects or the like can be newly exposed. As a result, a step of polishing the entire first surface 1a or another step can be skipped, and thus the productivity of semiconductor elements can be improved. Note that in this case, when the adhesive layer 5 and the support substrate 6 are used to pull and peel the first semiconductor layer 31 away from the substrate 1, the first semiconductor layer 31 may be pulled and peeled such that stress is applied to the substrate 1.

Furthermore, in separating the first element in the first element separating step d1, the first element may be separated, for example, after the region including a portion of the first semiconductor layer 31, which is in contact with the substrate 1 is removed. In other words, the first semiconductor layer 31 located on the first mask is obtained as the first element (or a portion of the first element), and the residual portion is removed; thereafter, the first element (or a portion of the first element) may be separated with the use of the adhesive layer 5 and the support substrate 6. Note that in this case, the first mask may be removed after the adhesive layer 5 and the support substrate 6 are adhered to the first semiconductor layer 31. Note that by removing the first mask, the first element can be easily separated from the substrate 1.

Further, although an example where a silicon oxide layer is provided as the deposition inhibiting mask 2 is described, the deposition inhibiting mask 2 may use a material to which the material of the semiconductor layer 3 is less prone to adhere, and may be, for example, a layer of fluorine resin. Furthermore, for the deposition inhibiting mask 2, fluorine treatment may be applied to a surface of a layer made of an inorganic or organic material. In addition, for the deposition inhibiting mask 2, fluorine treatment is directly applied to the region, excluding the first region R1, the second region R2, or the third region R3, of the first main surface a of the substrate 1, and thus the function as the deposition inhibiting mask 2 may be attained. By using a fluorine-based material, the growth of the semiconductor layer 3 can be reduced.

Moreover, although an example where the first mask 21 is removed before the first element is separated, the first mask 21 may be used as the second mask 22 or the third mask 23 without removing the first mask 21.

The present disclosure can be embodied in the following aspects.

A method for manufacturing a semiconductor element of the present disclosure includes: a step of preparing a substrate; a first element forming step of forming a first semiconductor layer in a first region on a surface of the substrate; a first element separating step of separating the first semiconductor layer from the substrate; and a second element forming step of forming a second semiconductor layer in a second region on the surface of the substrate from which the first semiconductor layer is separated. At least a portion of the second region is configured to overlap the first region.

According to the method for manufacturing a semiconductor element of the present disclosure, by reducing the number of steps in manufacturing a semiconductor element and by improving the quality of the semiconductor element, the productivity of semiconductor elements can be improved.

1. A method for manufacturing a semiconductor element, comprising:
a step of preparing a substrate;
a first element forming step of forming a first semiconductor layer in a first region on a first surface of the substrate;
a first element separating step of separating the first semiconductor layer from the substrate; and
a second element forming step of forming a second semiconductor layer in a second region on the first surface of the substrate from which the first semiconductor layer is separated, wherein at least a portion of the second region overlaps the first region.

2. The method for manufacturing a semiconductor element according to claim 1, comprising:
a first mask forming step of forming a first mask on the first surface of the substrate while exposing the first region after the step of preparing the substrate; and
a first mask removing step of removing the first mask before the first element separating step.

3. The method for manufacturing a semiconductor element according to claim 1, wherein the first region and the second region are a plurality of strip-shaped regions.

4. The method for manufacturing a semiconductor element according to claim 1, wherein the first region and the second region are grid regions.

5. The method for manufacturing a semiconductor element according to claim 1, wherein the second region is smaller than the first region.

6. The method for manufacturing a semiconductor element according to claim 1, wherein in the first element separating step, the first element is separated along with a portion of the substrate with which the first element is in contact.

7. The method for manufacturing a semiconductor element according to claim 1, comprising:
a second mask forming step of forming a second mask on the first surface of the substrate while exposing the second region, at least a portion of the second region overlapping the first region, on the substrate from which the first semiconductor layer is separated.

8. The method for manufacturing a semiconductor element according to claim 7, further comprising:
a second mask removing step of removing the second mask; and
a second element separating step of separating the second semiconductor layer from the substrate,
wherein the second mask forming step, the second element forming step, the second mask removing step, and the second element separating step are repeated one or more times.

9. The method for manufacturing a semiconductor element according to claim 1, comprising:
a cleaning step of cleaning at least a surface of a portion of the first surface of the substrate after the first element separating step and before the second element forming step.

10. The method for manufacturing a semiconductor element according to claim 1, further comprising:
a polishing step of polishing at least a portion of the first surface of the substrate after the first element separating step and before the second element forming step.

11. The method for manufacturing a semiconductor element according to claim 1, further comprising:
a second element separating step of separating the second semiconductor layer from the substrate,
a third mask forming step of forming a third mask on the first surface of the substrate while exposing a third region, at least a portion of the third region overlapping the second region, on the substrate from which the second semiconductor layer is separated; and
a third element forming step of forming a third semiconductor layer in the third region.

12. The method for manufacturing a semiconductor element according to claim 11, wherein at least a portion of the third region overlaps the first region.

13. The method for manufacturing a semiconductor element according to claim 12, wherein the third region is separated from the first region.

14. The method for manufacturing a semiconductor element according to claim 11, further comprising:
a polishing step of polishing at least a portion of the first surface of the substrate after the second element separating step and before the third element forming step.

15. The method for manufacturing a semiconductor element according to claim 11, further comprising:
a substrate growing step of, after the second element separating step or the third element separating step, increasing a thickness of the substrate from which the second element or the third element is peeled.

16. The method for manufacturing a semiconductor element according to claim 1, wherein an edge region of the first surface is covered with a first mask.

17. The method for manufacturing a semiconductor element according to claim 1, wherein a protective layer is formed on a second surface located on an opposite side of the first surface of the substrate.

18. The method for manufacturing a semiconductor element according to claim 1, wherein a first mask including silicon oxide is used.

19. The method for manufacturing a semiconductor element according to claim 1, wherein a first mask including at least one element of a group of elements containing tungsten, molybdenum, tantalum, and niobium.
